(19) United States
(12) Patent Application Publication
(10) Pub. No.: US 2026/0232025 A1
(43) Pub. Date: Aug. 13, 2026

(54) AEROSOL PROVISION DEVICE COMPRISING A SENSOR COIL

(71) Applicant: NICOVENTURES TRADING LIMITED, London (GB)

(72) Inventor: Zhihuang XIAO, London (GB)

(21) Appl. No.: 19/153,027

(22) PCT Filed: Jan. 31, 2024
(86) PCT No.: PCT/EP2024/052403

§ 371 Date: Aug. 1, 2025

(30) Foreign Application Priority Data
Feb. 1, 2023 (GB) 2301456.6

(51) Int. Cl. A24F 40/465; A24F 40/20; A24F 40/51; A24F 40/53; A24F 40/57; G01R 27/26

(52) U.S. Cl. CPC A24F 40/465; A24F 40/20; A24F 40/51; A24F 40/53; A24F 40/57; G01R 27/2611

(57) ABSTRACT

An aerosol provision device configured to receive at least a portion of an article comprising aerosol generating material. The aerosol provision device comprises a sensor coil and a processor. The processor is configured to detect a reactance relating to the sensor coil resulting from the article being received by the aerosol provision device. The processor is configured to determine article information from the reactance.

### TECHNICAL FIELD

The present invention relates to an aerosol provision device and an aerosol provision system.

### BACKGROUND

Smoking articles such as cigarettes, cigars and the like burn tobacco during use to create tobacco smoke. Attempts have been made to provide alternatives to these articles that burn tobacco by creating products that release compounds without burning. Examples of such products are heating devices which release compounds by heating, but not burning, the material. The material may be for example tobacco or other non-tobacco products, which may or may not contain nicotine.

### SUMMARY

In accordance with a first aspect, there is provided an aerosol provision device configured to receive at least a portion of an article comprising aerosol generating material, the aerosol provision device comprising: a sensor coil; and a processor configured to detect a reactance relating to the sensor coil resulting from the article being received by the aerosol provision device, the processor configured to determine article information from the reactance.

The processor may be configured to determine a resonant frequency of the coil to determine the reactance of the sensor coil.

The aerosol provision device may comprise a receptacle configured to receive the portion of the article, wherein the sensor coil at least partially surrounds the receptacle

The processor may be configured to authenticate the article in response to the article information.

The processor may be configured to select a heating session in response to the article information.

The processor may be configured to modify a heating profile in response to the property of the article.

The processor may be configured to modify a session length in response to the property of the article.

The processor may be configured to modify an operating temperature in response to the property of the article.

The article information may comprise the presence of the article in the aerosol provision device.

The article information may comprise a type of the article.

The article information may comprise a unique article identifier.

The reactance may comprise an inductance.

The reactance may comprise an inductance measured across the sensor coil, the processor configured to determine the article information from the inductance.

The aerosol provision device may comprise an aerosol generator, the aerosol generator comprising a heater coil.

The sensor coil may be adjacent to the heater coil of the aerosol generator.

The sensor coil may be within the pitch of the heater coil.

The sensor coil may surround the heater coil.

The sensor coil may be longitudinally displaced relative to the heater coil.

The sensor coil may be arranged closer to a mouth end of the aerosol generating device than the heater coil.

The sensor coil may comprise more than 50 turns.

The reactance may comprise a capacitance.

The reactance may comprise a capacitance measured between the sensor coil and the heater coil, the processor configured to determine the article information from the capacitance.

The aerosol provision device may comprise an amplifier arranged to amplify an output from the sensor coil.

The sensor coil may be formed on a flexible printed circuit board (PCB).

The aerosol provision device may comprise an article sensor arranged to detect insertion of an article in the aerosol provision device. The may processor configured to detect a change in capacitance of the sensor coil in response to the article sensor detect insertion of the article.

The article sensor may comprise a hall sensor configured to detect a change in a magnetic field resulting from the article being received by the aerosol provision device.

The article sensor may comprise a mechanical sensor actuatable by insertion of the article in the aerosol provision device.

The article sensor may comprise a light sensor configured to receive light from the article. The light may be reflected from the article. The article sensor may comprise a light transmitter configured to transmit light to the article to cause light to be reflected from the article.

The article sensor may comprise a laser sensor.

The article sensor may comprise a camera configured to receive an image from the article.

The aerosol provision device may be a tobacco heating product.

According to a second aspect, there is provided an article comprising aerosol generating material.

The article may comprise a heatable element. The heatable element may be formed of metal or a metal alloy. The heatable element may be configured to produce heat on penetration with a varying magnetic field resulting from varying current in the heater coil.

According to a third aspect, there is provided an aerosol provision system comprising an aerosol provision device according to the first aspect and an article according to the second aspect.

According to a fourth aspect, there is provided a method of operating an aerosol provision device, the method comprising detecting a reactance relating to a sensor coil resulting from an article being received by the aerosol provision device and determining article information from the capacitance.

The aerosol provision system may comprise any of the features described with respect to the aerosol provision device and/or article. The method may comprise any of the features or steps described with respect to the aerosol provision device, the article and/or the aerosol provision system.

### BRIEF DESCRIPTION OF THE DRAWINGS

Embodiments will now be described, by way of example only, and with reference to the accompanying drawings in which:

FIG. 1 shows a side view of an aerosol provision system;

FIG. 2 shows a perspective view of an article;

FIG. 3 shows a schematic cross-sectional view of an aerosol provision system;

FIG. 4 shows a schematic cross-sectional view of an aerosol provision system;

FIG. 5 shows a schematic cross-sectional view of an aerosol provision system;

FIG. 6 shows a schematic view of an aerosol provision system; and

FIG. 7 shows a schematic view of an aerosol provision system.

### DETAILED DESCRIPTION

As used herein, the term “aerosol-generating material” is a material that is capable of generating aerosol, for example when heated, irradiated or energized in any other way. Aerosol-generating material may, for example, be in the form of a solid, liquid or gel which may or may not contain an active substance and/or flavourants. Aerosol-generating material may include any plant based material, such as tobacco-containing material and may, for example, include one or more of tobacco, tobacco derivatives, expanded tobacco, reconstituted tobacco or tobacco substitutes. Aerosol-generating material also may include other, non-tobacco, products, which, depending on the product, may or may not contain nicotine. Aerosol-generating material may for example be in the form of a solid, a liquid, a gel, a wax or the like. Aerosol-generating material may for example also be a combination or a blend of materials. Aerosol-generating material may also be known as “smokable material”.

The aerosol-generating material may comprise a binder and an aerosol former. Optionally, an active and/or filler may also be present. Optionally, a solvent, such as water, is also present and one or more other components of the aerosol-generating material may or may not be soluble in the solvent. In some embodiments, the aerosol-generating material is substantially free from botanical material. In some embodiments, the aerosol-generating material is substantially tobacco free.

The aerosol-generating material may comprise or be an “amorphous solid”. The amorphous solid may be a “monolithic solid”. In some embodiments, the amorphous solid may be a dried gel. The amorphous solid is a solid material that may retain some fluid, such as liquid, within it. In some embodiments, the aerosol-generating material may, for example, comprise from about 50 wt %, 60 wt % or 70 wt % of amorphous solid, to about 90 wt %, 95 wt % or 100 wt % of amorphous solid.

The aerosol-generating material may comprise an aerosol-generating film. The aerosol-generating film may comprise or be a sheet, which may optionally be shredded to form a shredded sheet. The aerosol-generating sheet or shredded sheet may be substantially tobacco free.

According to the present disclosure, a “non-combustible” aerosol provision system is one where a constituent aerosol-generating material of the aerosol provision system (or component thereof) is not combusted or burned in order to facilitate delivery of at least one substance to a user.

In some embodiments, the delivery system is a non-combustible aerosol provision system, such as a powered non-combustible aerosol provision system.

In some embodiments, the non-combustible aerosol provision system is an electronic cigarette, also known as a vaping device or electronic nicotine delivery system (END), although it is noted that the presence of nicotine in the aerosol-generating material is not a requirement.

In some embodiments, the non-combustible aerosol provision system is an aerosol-generating material heating system, also known as a heat-not-burn system. An example of such a system is a tobacco heating system.

In some embodiments, the non-combustible aerosol provision system is a hybrid system to generate aerosol using a combination of aerosol-generating materials, one or a plurality of which may be heated. Each of the aerosol-generating materials may be, for example, in the form of a solid, liquid or gel and may or may not contain nicotine. In some embodiments, the hybrid system comprises a liquid or gel aerosol-generating material and a solid aerosol-generating material. The solid aerosol-generating material may comprise, for example, tobacco or a non-tobacco product.

Typically, the non-combustible aerosol provision system may comprise a non-combustible aerosol provision device and a consumable for use with the non-combustible aerosol provision device.

In some embodiments, the disclosure relates to consumables comprising aerosol-generating material and configured to be used with non-combustible aerosol provision devices. These consumables are sometimes referred to as articles throughout the disclosure.

In some embodiments, the non-combustible aerosol provision system, such as a non-combustible aerosol provision device thereof, may comprise a power source and a controller. The power source may, for example, be an electric power source or an exothermic power source. In some embodiments, the exothermic power source comprises a carbon substrate which may be energised so as to distribute power in the form of heat to an aerosol-generating material or to a heat transfer material in proximity to the exothermic power source.

In some embodiments, the non-combustible aerosol provision system may comprise an area for receiving the consumable, an aerosol generator, an aerosol generation area, a housing, a mouthpiece, a filter and/or an aerosol-modifying agent.

In some embodiments, the consumable for use with the non-combustible aerosol provision device may comprise aerosol-generating material, an aerosol-generating material storage area, an aerosol-generating material transfer component, an aerosol generator, an aerosol generation area, a housing, a wrapper, a filter, a mouthpiece, and/or an aerosol-modifying agent.

An aerosol generating device can receive an article comprising aerosol generating material for heating. An “article” in this context is a component that includes or contains in use the aerosol generating material, which is heated to volatilise the aerosol generating material, and optionally other components in use. A user may insert the article into the aerosol generating device before it is heated to produce an aerosol, which the user subsequently inhales. The article may be, for example, of a predetermined or specific size that is configured to be placed within a heating chamber of the device which is sized to receive the article.

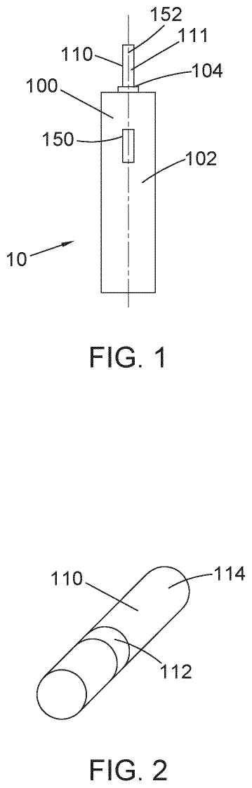

With reference to FIG. 1, an aerosol provision system 10 comprises an aerosol provision device 100 for generating aerosol from an aerosol generating material. The aerosol provision system 10 further comprises a replaceable article 110 comprising the aerosol generating material. In broad outline, the aerosol forming device 100 may be used to heat the article 110 to generate an aerosol or other inhalable medium, which is inhaled by a user of the device 100.

The aerosol forming device 100 comprises a body 102. A housing arrangement surrounds and houses various components of the body 102. An article aperture 104 is formed at one end of the body 102, through which the article 110 may be inserted for heating by an aerosol generator 200.

The device 100 may also include a user-operable control element 150, such as a button or switch, which operates the device 100 when pressed. For example, a user may turn on the device 100 by operating the switch 150.

The aerosol generator 200 defines a longitudinal axis, which aligns with an axis of the article 110.

In use, the article 110 may be fully or partially inserted into the aerosol generator 200 where it may be heated by one or more components of the aerosol generator 200.

The device 100 includes an apparatus for heating aerosol-generating material. The apparatus includes an aerosol generating assembly, a controller (control circuit), and a power source. The apparatus forms part of the body 102. The aerosol generating assembly is configured to heat the aerosol-generating material of an article 110 inserted through the article aperture 104, such that an aerosol is generated from the aerosol generating material. The power source supplies electrical power to the aerosol generating assembly, and the aerosol generating assembly converts the supplied electrical energy into heat energy for heating the aerosol-generating material. The power source may be, for example, a battery, such as a rechargeable battery or a non-rechargeable battery. Examples of suitable batteries include, for example, a lithium battery (such as a lithium-ion battery), a nickel battery (such as a nickel-cadmium battery), and an alkaline battery.

The power source may be electrically coupled to the aerosol generating assembly to supply electrical power when required and under control of the controller to heat the aerosol generating material. The control circuit may be configured to activate and deactivate the aerosol generating assembly based on a user input. The user input may be via a button press or opening a door of the device (for example, a door covering a consumable receiving receptacle). The control circuit may be configured to activate and deactivate automatically, for example on insertion of an article.

The aerosol generating assembly may comprise various components to heat the aerosol generating material via an inductive heating process. Induction heating is a process of heating an electrically conducting heating element (such as a susceptor) by electromagnetic induction. An induction heating assembly may comprise an inductive element, for example, one or more inductor coils, and a device for passing a varying electric current, such as an alternating electric current, through the inductive element. The varying electric current in the inductive element produces a varying magnetic field. The varying magnetic field penetrates a susceptor (heating element) suitably positioned with respect to the inductive element, and generates eddy currents inside the susceptor. The susceptor has electrical resistance to the eddy currents, and hence the flow of the eddy currents against this resistance causes the susceptor to be heated by Joule heating. In cases where the susceptor comprises ferromagnetic material such as iron, nickel or cobalt, heat may also be generated by magnetic hysteresis losses in the susceptor, i.e. by the varying orientation of magnetic dipoles in the magnetic material as a result of their alignment with the varying magnetic field. In inductive heating, as compared to heating by conduction for example, heat is generated inside the susceptor, allowing for rapid heating. Further, there need not be any physical contact between the inductive element and the susceptor, allowing for enhanced freedom in construction and application.

With reference to FIG. 2, the article 110 comprises an indicator portion 112. The indicator portion 112 is on an outer surface 114 of the article 110. The outer surface 114 may be formed from paper, with the indicator portion 112 printed on the paper. The indicator portion 112 is a band which surrounds the article 110. The indicator portion 112 encircles the article 110. The indicator portion 112 is a coloured portion.

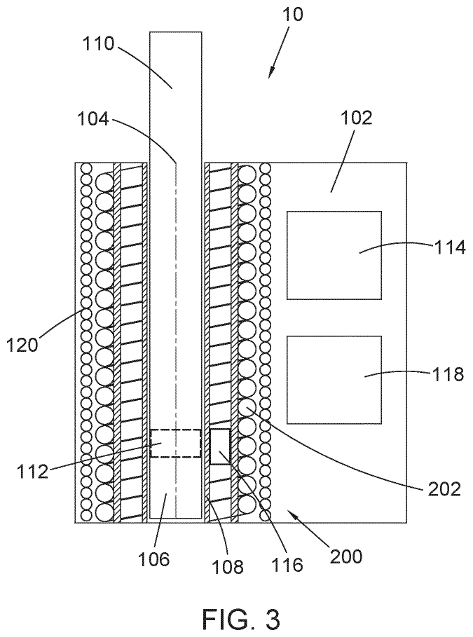

With reference to FIG. 3, a portion of the article 110 is received in a receptacle 106 of the aerosol provision device 100. The receptacle 106 is a cylindrical chamber, extending from the article aperture 104 into the body 102. The article 110 is inserted through the aperture 104 into the receptacle 106, such that the identifier 112 is positioned with the receptacle 106. The receptacle 106 is defined by a wall 108.

The aerosol provision device 100 comprises an aerosol generator 200. The aerosol generator 200 is a heating assembly. The aerosol generator 200 comprises an inductive element 202. The inductive element 202 is an inductive coil surrounding the receptacle 106. The aerosol generator 200 comprises a susceptor element 108, which, in the present embodiment, is the wall 108.

The aerosol provision device 100 comprises an article sensor 116. The receptacle 108 comprises an opening 109. The article sensor 116 is positioned at the opening 109. The article sensor 116 is positioned outside the receptacle 108 beyond the opening 109, such that the article sensor 116 is in optical communication with the receptacle through the opening 109. In some embodiments, the wall 108 comprises a translucent portion, with the article sensor 116 located outside the wall 108 beyond the translucent portion.

The article sensor 116 is positioned such that when the article 110 is received in the receptacle 106, the indicator portion 112 is aligned with the article sensor 116. In the present example, the article sensor 116 is a light sensor, comprising a light transmitter and a light receiver. In some examples, the article sensor may be a laser sensor. In some examples, the light receiver may be a camera.

The aerosol provision device 100 comprises a processor 118 in data communication with the article sensor 116.

The aerosol provision device 100 comprises a reactance sensor. The reactance sensor comprises a sensor coil 120. The aerosol provision device 100 comprises an amplifier 114, which is configured to amplify a signal from the sensor coil 120.

The sensor coil 120 surrounds the receptacle, thereby surrounding the article 110 in use. The sensor coil 120 is adjacent to the inductive element 202. The sensor coil 120 surrounds the inductive element 202. The sensor coil 120 is formed on a flexible printed circuit board (PCB). The sensor coil 120 comprises at least 50 turns, more specifically, substantially 100 turns.

In use, a user inserts the article 110 into the aerosol provision device 100. The article sensor 116 transmits a first light signal to the indicator portion 112. The first light signal reflects from the indicator portion 112 to provide a second light signal. The second light signal is received by the article sensor 116. The processor 118 determines from the second light signal that the article has been received by the aerosol provision device. In other examples, the article sensor 116 is omitted, and the sensor coil 120 determines (e.g. from a change in reactance relating to the sensor coil) that the article 10 has been received in the aerosol provision device 100.

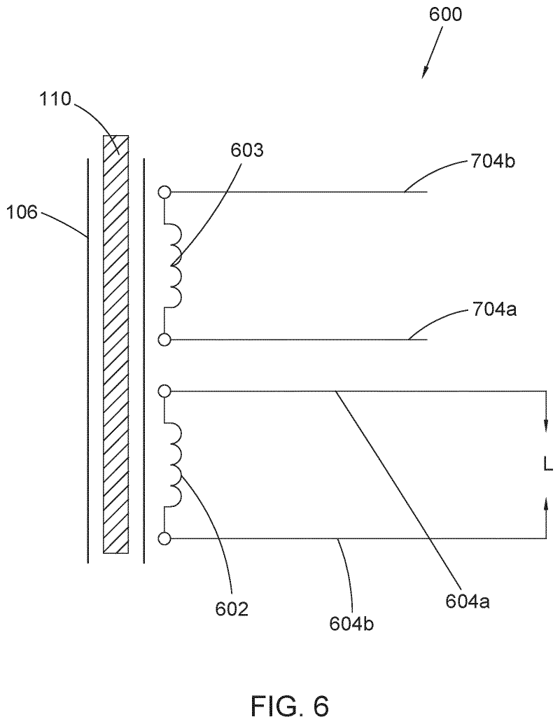

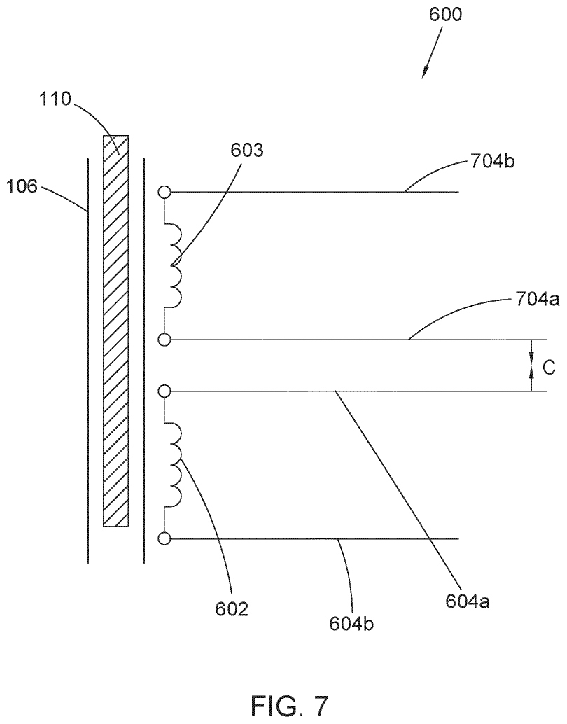

In response to determining that the article has been received by the aerosol provision device, the processor 118 performs an article identification process. During the article identification process, the processor detects a reactance relating to the sensor coil 120. Examples of the reactance relating to the sensor coil 20 are described below with respect to FIG. 6 and FIG. 7. The amplifier 114 amplifies a signal from the sensor coil 120 to permit the processor to detect the reactance. The processor 118 may determine an electrical resonance frequency of the sensor coil 120 to determine the reactance relating to the sensor coil 120.

The reactance is dependent on properties of the article 110 received by the aerosol provision device 102. As such, the reactance indicates article information. In particular, the article 110 may comprise a metallic material, with the reactance dependent on properties of the metallic material e.g. the dimensions of the material, its thickness, its permeability, its location in the article and spacing from the sensor coil. The metallic material may be in the form of a foil e.g. an aluminium foil. The metallic material may also form part of the heating assembly, and may act as a susceptor.

The article information comprises a type of the article. In some examples, the article information comprises an authentication status of the article.

The aerosol generator 200 generates an aerosol from the article 110 in response to user actuation of the user controllable element 150. The aerosol provision device 100 supplies an alternating current to the inductor element 202, which causes the susceptor element 108 to heat the aerosol generating material of the article 110.

The susceptor element 108 heats the aerosol generating material by applying a heating profile, with an operating temperature, over an aerosol generating session. The heating profile may be dependent on the article information, with different heating profiles being applied for different types of article. The operating temperature is dependent on article information, with the aerosol generating material being heated to different operating temperatures in different types of article. The session length (i.e. a time period during which the aerosol generator generates from the aerosol generating material) of the aerosol generating session is dependent on article information, with different session lengths being used for different types of article.

In other examples, where the article information comprises an authentication status of the article, in response to determining that the article is not authenticated for use with the aerosol provision device, the processor 118 prevents the aerosol generation session from beginning.

At the end of the aerosol generating session, the aerosol generator 200 stops generating aerosol from the aerosol generating material. The user removes the article 110 from the aerosol provision device 100 and disposes of the article 110.

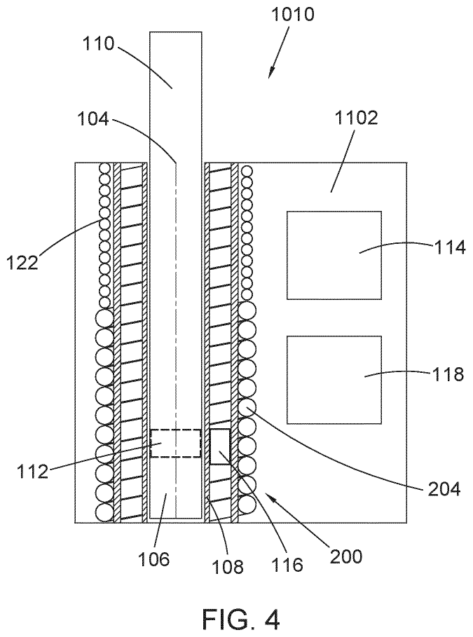

FIG. 4 shows a second aerosol provision system 1010 comprising a second aerosol provision device 1102, which comprise many of the same features as the aerosol provision system 10 and aerosol provision device 102. Repeated description of those features is omitted, with only the differences described here.

The second aerosol provision device 1102 comprises a second sensor coil 122 and a second inductive element 204 (again, a heater coil). In contrast to the inductive element 202, the second inductive element 204 does not extend to the mouth end of the second aerosol provision device 1102. The second sensor coil 122 is longitudinally displaced relative to the heater coil 204. The second sensor coil 122 is adjacent to the heater coil 204. The second sensor coil 122 is radially aligned with heater coil 204. The second sensor coil 122 is closer to a mouth end of the aerosol generating device than the heater coil 204. The second aerosol provision system 110 operates in the same manner as the aerosol provision system 10.

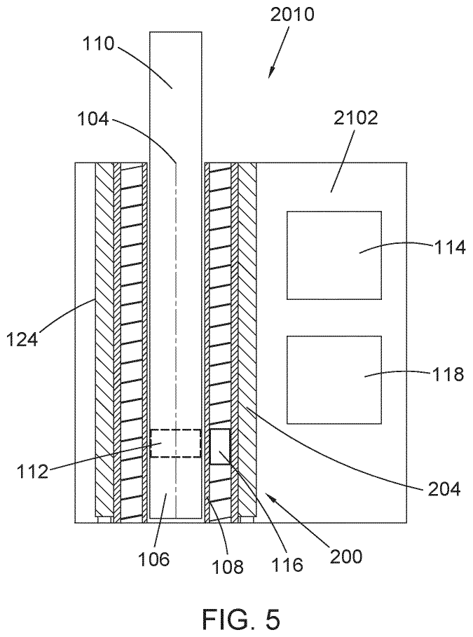

FIG. 5 shows a third aerosol provision system 2010 comprising a third aerosol provision device 2102, which comprise many of the same features as the aerosol provision system 10 and aerosol provision device 102. Repeated description of those features is omitted, with only the differences described here.

The third aerosol provision device 2102 comprises a third sensor coil 124 and a third inductive element 206. The third inductive element 206 is a heater coil 206. The third sensor coil 124 is wound within the heater coil 206. The third sensor coil 124 extends substantially a full length of the heater coil 206 in the longitudinal direction.

FIG. 6 and FIG. 7 show an aerosol provision system 600 which comprises many of the same features as the aerosol provision system 10 to illustrate how the reactance relating to the sensor coil is determined. Repeated description of those features is omitted, with only the differences described here. Some features are also omitted from the figures for clarity.

In the configuration of FIG. 6 and FIG. 7, the aerosol provision device comprises a fourth sensor coil 602 and a fourth inductive element 603 (again a heater coil 603). A second terminal 604b of the sensor coil 602 is connected to an analogue ground. Terminals 704a 704b located either side of the heater coil 603 are connected to induction power circuitry to supply power to the heater coil 603 for heating.

In the configuration of FIG. 6, the reactance relating to the fourth sensor coil 602 comprises an inductance L measured across the sensor coil 602. The inductance L is measured across terminals 604a 604b either side of the sensor coil 602 (e.g. by connecting sensing circuitry to those terminals). The inductance L value may change when an article 110 is inserted into the receptacle 106. This is caused by a change in permeability within an area surrounded by the sensor coil 602, wherein the change in permeability is dependent on properties of the article 110. In use, the processor detects the inductance L and determines article information (described above) from the inductance L.

In the configuration of FIG. 7, the reactance relating to the sensor coil 602 comprises a capacitance C measured between the sensor coil 602 and the fourth inductive element 603. In this arrangement the sensor coil 602 acts as a first electrode plate of a capacitor, and the heater coil 603 acts as a second electrode plate of the capacitor. In this embodiment, the capacitance C is measured across the first terminal 604a of the sensor coil 602 and the first terminal 704a of the heater coil 603 (e.g. by connecting sensing circuitry to those terminals). The first terminal 604a of the sensor coil 602 and the first terminal 704a of the heater coil 603 are adjacent to each other, with neither coil positioned between the terminals. In other embodiments, capacitance may instead be measured across a second terminal 604b of the sensor coil 602 and/or a second terminal 704b of the heater coil 603, such that the sensor coil 602 and/or the heater coil 603 is between the terminals. In other embodiments, capacitance may instead be measured across any combination of terminals, wherein the terminals comprise a terminal 604a 604b of the sensor coil 602, and a terminal 704a 704b of the heater coil 603. The capacitance C value may change when an article 110 is inserted into the receptacle 106. This is caused by a change in permittivity within an area between the sensor coil 602 and the heater coil 603, wherein the change in permittivity is dependent on properties of the article 110.

FIG. 6 and FIG. 7 show example configurations in which the heater coil 603 is longitudinally displaced from the sensor coil 602, and the heater coil 603 is arranged closer to a mouth end of the aerosol provision device than the sensor coil 602. This does not exclude other configurations which may be used when detecting inductance and capacitance values within the aerosol provision system as described with respect to FIGS. 6 and 7. In particular, in other embodiments, capacitance (e.g. between the sensor coil and the heater coil as in FIG. 7) and/or inductance (e.g. across the sensor coil as in FIG. 6) may be measured in a configuration wherein the heater coil 603 is longitudinally displaced from the sensor coil 602, and the sensor coil 602 is arranged closer to the mouth end of the aerosol provision device than the heater coil 603 (such as that described with respect to FIG. 4). In other embodiments, capacitance (e.g. between the sensor coil and the heater coil as in FIG. 7) and/or inductance (e.g. across the sensor coil as in FIG. 6) may be measured in a configuration wherein the sensor coil 602 surrounds the heater coil 603 (such as that described with respect to FIG. 3). In other embodiments, capacitance (e.g. between the sensor coil and the heater coil as in FIG. 7) and/or inductance (e.g. across the sensor coil as in FIG. 6) may be measured in a configuration wherein the sensor coil 602 is wound within the heater coil 603 (such as that described with respect to FIG. 5).

In some embodiments, the configurations shown in FIG. 6 and FIG. 7 may be used simultaneously, such that both capacitance C and inductance L can be measured. This may improve data accuracy relating to the insertion of the article 110.

In the above described embodiments, the aerosol provision device comprises a heating arrangement that is an inductive heating arrangement. In embodiments, other types of heating arrangement are used, such as resistive heating. The configuration of the device is generally as described above and so a detailed description will be omitted. In such arrangements the aerosol generating assembly comprises a resistive heating generator including components to heat the heating element via a resistive heating process. In this case, an electrical current is directly applied to a resistive heating component, and the resulting flow of current in the heating component causes the heating component to be heated by Joule heating. The resistive heating component comprises resistive material configured to generate heat when a suitable electrical current passes through it, and the heating assembly comprises electrical contacts for supplying electrical current to the resistive material.

In embodiments, the heating element forms the resistive heating component itself. In embodiments the resistive heating component transfers heat to the heating element, for example by conduction.

The various embodiments described herein are presented only to assist in understanding and teaching the claimed features. These embodiments are provided as a representative sample of embodiments only, and are not exhaustive and/or exclusive. It is to be understood that advantages, embodiments, examples, functions, features, structures, and/or other aspects described herein are not to be considered limitations on the scope of the invention as defined by the claims or limitations on equivalents to the claims, and that other embodiments may be utilised and modifications may be made without departing from the scope of the claimed invention. Various embodiments of the invention may suitably comprise, consist of, or consist essentially of, appropriate combinations of the disclosed elements, components, features, parts, steps, means, etc, other than those specifically described herein. In addition, this disclosure may include other inventions not presently claimed, but which may be claimed in future.

1. An aerosol provision device configured to receive at least a portion of an article comprising aerosol generating material, the aerosol provision device comprising:
a sensor coil; and
a processor configured to detect a reactance relating to the sensor coil resulting from the article being received by the aerosol provision device, the processor configured to determine article information from the reactance.

2. An aerosol provision device according to claim 1 and comprising a receptacle configured to receive the portion of the article, wherein the sensor coil at least partially surrounds the receptacle.

3. An aerosol provision device according to claim 1, wherein the processor is configured to authenticate the article in response to the article information.

4. An aerosol provision device according to claim 1, wherein the processor is configured to select a heating session in response to the article information.

5. An aerosol provision device according to claim 1, wherein the article information comprises the presence of the article in the aerosol provision device and/or a type of the article.

6. An aerosol provision device according to claim 1, wherein the reactance comprises an inductance measured across the sensor coil, the processor configured to determine the article information from the inductance.

7. An aerosol provision device according to claim 1 and comprising an aerosol generator, the aerosol generator comprising a heater coil, wherein the sensor coil is adjacent to the heater coil.

8. An aerosol provision device according to claim 7, wherein the sensor coil is within the pitch of the heater coil of the aerosol generator.

9. An aerosol provision device according to claim 7, wherein the sensor coil is longitudinally displaced relative to the heater coil.

10. An aerosol provision device according to claim 9, wherein the sensor coil is arranged closer to a mouth end of the aerosol generating device than the heater coil.

11. An aerosol provision device according to claim 7, wherein the reactance comprises a capacitance measured between the sensor coil and the heater coil, the processor configured to determine the article information from the capacitance.

12. An aerosol provision device according to claim 1, wherein the sensor coil is formed on a flexible printed circuit board (PCB).

13. An aerosol provision device according to claim 1, and comprising an article sensor arranged to detect insertion of an article in the aerosol provision device.

14. An aerosol provision system comprising an aerosol provision device according to claim 1 and the article.

15. A method of operating an aerosol provision device, the method comprising detecting a reactance relating to a sensor coil and determining article information from the reactance.
